(19) United States
(12) Patent Application Publication
(10) Pub. No.: US 2010/0126765 A1
(43) Pub. Date: May 27, 2010

(54) MULTI-LAYER PRINTED CIRCUIT BOARD AND MANUFACTURING METHOD THEREOF

(75) Inventors: Ki-Hwan KIM, Boryeong-si (KR); Jin-Yong An, Yongin-si (KR); Jae-Joon Lee, Suwon-si (KR)

Correspondence Address: MCDERMOTT WILL & EMERY LLP, 600 13TH STREET, N.W., WASHINGTON, DC, 20005-3096, US

(73) Assignee: SAMSUNG ELECTRO-MECHANICS CO., LTD.

(21) Appl. No.: 12/569,104

(22) Filed: Sep. 29, 2009

(30) Foreign Application Priority Data
Nov. 26, 2008 (KR) 10-2008-0117921

(51) Int. Cl. H05K 1/11; B32B 38/00; B32B 38/10; C23F 1/00

(52) U.S. Cl. 174/262; 156/280; 156/272.8; 216/13

(57) ABSTRACT

A method of manufacturing a multi-layer PCB having external contact pads formed on one side can include: forming an outermost insulation layer, in which openings are formed corresponding with the external contact pads; forming a mask, in which openings are formed corresponding with the external contact pad and with a circuit pattern, on the outermost insulation layer; forming the external contact pads and the circuit pattern in the openings of the outermost insulation layer and the openings of the mask; removing the mask; forming a build-up layer by stacking layers over the outermost insulation layer such that the external contact pads and the circuit pattern are covered; forming a first solder resist layer on the build-up layer; and forming a second solder resist layer on an opposite side of the outermost insulation layer; and forming openings in the second solder resist layer such that the external contact pads are exposed.

### CROSS-REFERENCE TO RELATED APPLICATIONS

This application claims the benefit of Korean Patent Application No. 10-2008-0117921, filed with the Korean Intellectual Property Office on Nov. 26, 2008, the disclosure of which is incorporated herein by reference in its entirety.

### BACKGROUND

1. Technical Field

The present invention relates to a multi-layer printed circuit board and to a method of manufacturing the multi-layer printed circuit board.

2. Description of the Related Art

With electronic products trending towards smaller, thinner, more compactly packaged, portable products having higher densities, the multi-layer printed circuit board (PCB) is also undergoing a trend towards finer patterns and smaller, more compactly packaged products. Accordingly, various attempts have been made to form fine-lined patterns and increase the reliability and design density of the multi-layer PCB, including changing the type of raw material and integrating the layer composition of circuits. Components are also undergoing a change from DIP (dual in-line package) types to SMT (surface mount technology) types, so that the mounting density may also be increased.

A typical method of manufacturing a multi-layer circuit board for a thin semiconductor device may include preparing a carrier by using an adhesive material on the outer edges of two metal plates. Then, the two exposed faces may be plated with a metal having an etching mechanism that is different from those of the metal plates and the pads of the product to be manufactured. After building up multiple circuit layers on both sides of the product, the portions of the adhesive material may be removed to separate the two metal plates. Then, the metal plates that were used as the carrier may be removed with an etchant. At this time, the plated metal may be exposed, with the built-up circuit layers unaffected, and the metal may in turn be removed by etching to manufacture a multi-layer circuit board for a semiconductor device.

A thin multi-layer circuit board may be manufactured using the above process, but when used as a semiconductor board, the structure may include materials having different mechanical properties stacked together. The plating may be distributed differently on the upper and lower surfaces, and even when solder resists (SR) are used, this may create an anisotropic structure. Since an anisotropic stacked structure may exhibit different thermal behaviors for each layer according to thermal stresses and humidity conditions, the weaker portions of the structure may be subject to deformations such as bending and warpage.

### SUMMARY

An aspect of the invention provides a multi-layer printed circuit board, and a method of manufacturing the multi-layer circuit board, in which the thicknesses of the outermost insulation layers are made different on either side, so that the multi-layer printed circuit board is more resistant to warpage.

Another aspect of the invention provides a method of manufacturing a multi-layer printed circuit board that has at least one external contact pad formed on one side of the multi-layer printed circuit. The method may include: forming an outermost insulation layer, in which an opening is formed that corresponds with the external contact pad; forming a mask, in which an opening is formed that corresponds with the external contact pad and with a circuit pattern, on the outermost insulation layer; forming the external contact pad and the circuit pattern in the opening of the outermost insulation layer and in the opening of the mask; removing the mask; forming a build-up layer by stacking at least one layer over the outermost insulation layer such that the external contact pad and the circuit pattern are covered; forming a first solder resist layer on the build-up layer; and forming a second solder resist layer on a side of the outermost insulation layer opposite the side on which the build-up layer is formed; and forming an opening in the second solder resist layer such that the external contact pad is exposed.

In certain embodiments, the outermost insulation layer can be formed over a carrier, and the method can further include removing the carrier, before the forming of the second solder resist layer.

The carrier can include a metal layer on its surface, in which case the metal layer can contain a material that can be etched by a different etchant from that used for the external contact pad.

The opening in the outermost insulation layer can be formed by: stacking the outermost insulation layer on the metal layer of the carrier, and selectively removing the outermost insulation layer with a laser drill.

Along its perimeter, the build-up layer can include a dummy area, which may be removed from the completed multi-layer printed circuit board, and the carrier can include a separation layer that has an adhesive applied only to a portion of the separation layer corresponding with the dummy area. In this case, the removing of the carrier can include: removing the adhesive-applied portion of the separation layer by cutting the dummy area; and etching the metal layer.

Before the forming of the mask, the method can further include forming a seed layer. Then, the forming of the external contact pad and the circuit pattern can be performed by plating over the seed layer, and the method can further include removing the seed layer.

Another aspect of the invention provides a multi-layer printed circuit board that includes: a build-up layer formed by stacking at least one layer, which includes a via and a pattern, from one side to the other side of the build-up layer; a first solder resist layer stacked on the other side of the build-up layer; an outermost insulation layer stacked on one side of the build-up layer; an external contact pad, which is formed on one side of the build-up layer, and which penetrates the outermost insulation layer to be exposed at a surface; and a second solder resist layer, which is stacked on the outermost insulation layer, and in which an opening is formed that exposes the external contact pad.

Additional aspects and advantages of the present invention will be set forth in part in the description which follows, and in part will be obvious from the description, or may be learned by practice of the invention.

### BRIEF DESCRIPTION OF THE DRAWINGS

FIG. 1 is a flow diagram illustrating a method of manufacturing a multi-layer printed circuit board according to an aspect of the invention.

FIG. 2 is a cross-sectional view of a carrier utilized in a method of manufacturing a multi-layer printed circuit board according to an aspect of the invention.

FIG. 3 through FIG. 14 illustrate operations that may be included in a method of manufacturing a multi-layer printed circuit board according to an aspect of the invention.

FIG. 15 is a cross-sectional view of a multi-layer printed circuit board according to another aspect of the invention.

### DETAILED DESCRIPTION

As the invention allows for various changes and numerous embodiments, particular embodiments will be illustrated in the drawings and described in detail in the written description. However, this is not intended to limit the present invention to particular modes of practice, and it is to be appreciated that all changes, equivalents, and substitutes that do not depart from the spirit and technical scope of the present invention are encompassed in the present invention.

While such terms as “first” and “second,” etc., may be used to describe various elements, such elements must not be limited to the above terms. The above terms are used only to distinguish one element from another.

The terms used in the present specification are merely used to describe particular embodiments, and are not intended to limit the present invention. An expression used in the singular encompasses the expression of the plural, unless it has a clearly different meaning in the context. In the present specification, it is to be understood that the terms such as “including” or “having,” etc., are intended to indicate the existence of the features, numbers, steps, actions, elements, parts, or combinations thereof disclosed in the specification, and are not intended to preclude the possibility that one or more other features, numbers, steps, actions, elements, parts, or combinations thereof may exist or may be added.

The multi-layer printed circuit board and method of manufacturing a multi-layer printed circuit board according to certain embodiments of the invention will be described below in more detail with reference to the accompanying drawings. Those elements that are the same or are in correspondence are rendered the same reference numeral regardless of the figure number, and redundant descriptions are omitted.

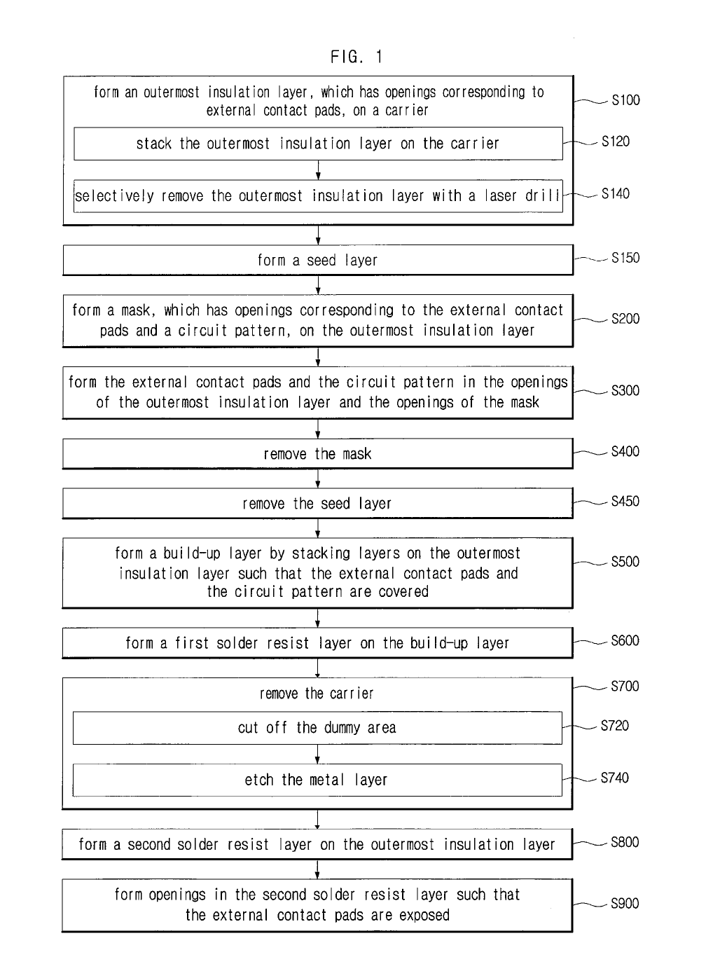

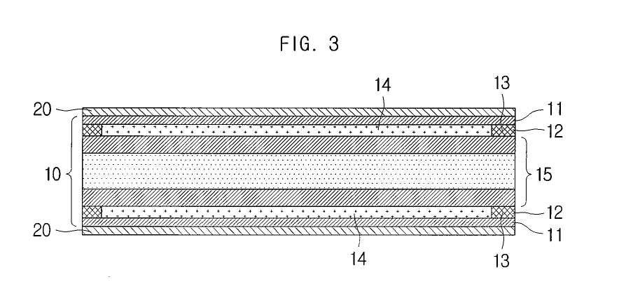

An aspect of the invention relates to a multi-layer printed circuit board (PCB), in which the insulation layers are stacked by two stacking processes, so that the thickness of the insulation layers on one side is greater than on the other side, and the thickness of the external contact pad on one side is greater than on the other side. FIG. 1 is a flow diagram illustrating a method of manufacturing a multi-layer PCB according to an aspect of the invention, and FIG. 3 through FIG. 14 illustrate operations that may be included in a method of manufacturing a multi-layer PCB according to an aspect of the invention. Illustrated in FIGS. 3 to 14 are a carrier 10, metal layers 11, separation layers 12, adhesive 13, separation members 14, a copper clad laminate (CCL) 15, outermost insulation layers 20, seed layers 25, masks 27, external contact pads 30, circuit patterns 35, build-up layers 40, layers 41, patterns 42, vias 43, first solder resist layers 50, and second solder resist layers 55.

Formed first can be an outermost insulation layer, in which openings may be formed corresponding to external contact pads 30 (S100). The outermost insulation layer 20 can be an extra layer added to a conventional multi-layer PCB and may include openings that are in correspondence with the external contact pads 30. Thus, the external contact pads 30 on one side of the multi-layer PCB may be formed thicker than the external contact pads on the other side by the thickness of the outermost insulation layer 20.

When manufacturing the multi-layer PCB, a carrier can be used as a base member. The carrier may serve as a base member on which to perform build-up processes in a stable manner when forming a thin multi-layer PCB, and may be removed from the final product of the multi-layer PCB. Using a carrier in performing the stacking operations for the PCB can prevent warpage, which may otherwise occur during the manufacturing process of the thin PCB, and can better facilitate transport of the thin board.

A certain degree of strength is required in the material forming the carrier if the carrier is to function as a stable base member. Also, since the carrier is to be separated from the final product, it may be desirable to form the carrier such that it can readily be separated. Various materials and various layer compositions can be selected for the carrier, in consideration of the above criteria.

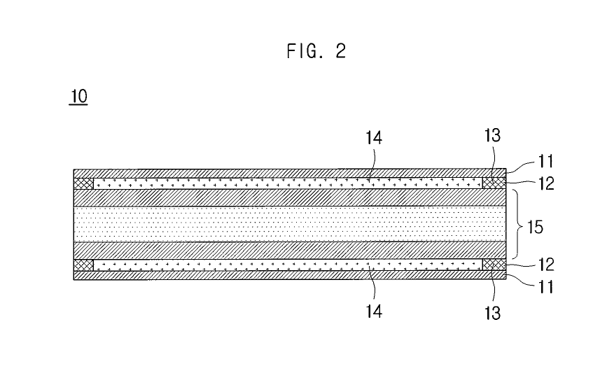

Accordingly, this embodiment may employ a carrier 10 such as that illustrated in FIG. 2. The carrier 10 may include a high-strength core, such as a copper clad laminate (CCL) 15, as a major constituent and may serve as a base member during the build-up operations for the multi-layer PCB.

In order that the carrier 10 may readily be separated from the final product, a separation layer 12 can be formed on either surface of the CCL 15. A dummy area, including alignment marks, etc., for placing indicators required during the process may exist along the perimeter of the build-up layer, outside the portions having circuit patterns, etc., that will remain in the final product of the PCB. The dummy area may be removed from the final product by routing, etc. The separation layer 12 may include adhesive 13 applied only on the positions where the dummy area is formed. When the dummy area is cut off, the adhesive 13 may be removed, so that the carrier 10 may be separated easily. The separation member 14 may be a member that does not itself provide adhesion, and may thus be separated from the PCB when the adhesive is removed. In cases where the adhesive is thinly applied, the separation member 14 can be omitted.

A metal layer 11, which is formed on each outermost layer of the carrier 10 and on which the multi-layer PCB may be stacked, can also be included. If the metal layer 11 is formed on the separation layer 12, the separation layer 12 and the CCL 15 may be removed from the final product, but the metal layer 11 may remain on the multi-layer PCB. The metal layer 11 may then be removed by an etching process, etc. A more detailed description of the metal layer 11 will be provided later in the descriptions for the operation of forming the outermost insulation layer.

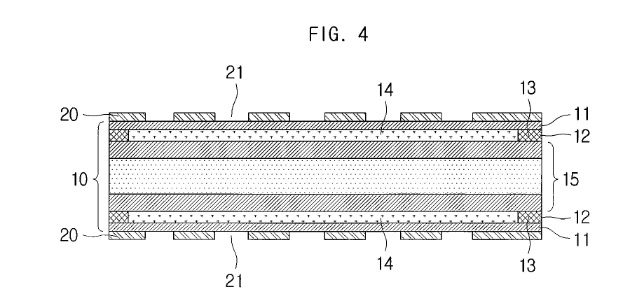

A method of forming openings 21 in the outermost insulation layer 20 using a carrier such as that described above can include stacking the outermost insulation layer 20 on the carrier 10 (S120) and selectively removing the outermost insulation layer 20 with a laser drill (S140) (see FIG. 3 and FIG. 4).

The selectively removed portions may correspond to positions where the external contact pads 30 are to be formed. The external contact pads 30 serve as terminals, by which an external device such as a semiconductor chip may be connected to the multi-layer PCB, and are exposed at the surface of the completed multi-layer PCB.

In stacking the outermost insulation layer 20 on the carrier 10 and forming openings 21 with a laser drill, having the metal layer 11 on the surface of the carrier 10 can prevent the carrier 10 from being penetrated.

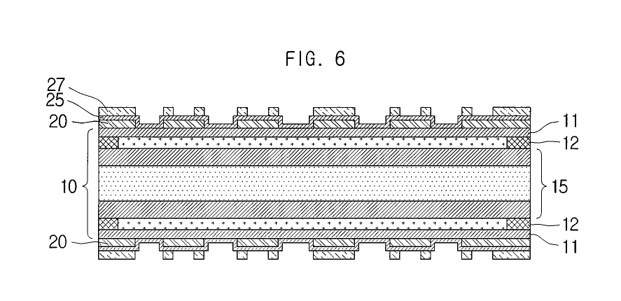

Next, as illustrated in FIG. 6, a mask 27, in which an opening is formed that corresponds with the external contact pads 30 and a circuit pattern 35, may be formed on the outermost insulation layer 20 (S200). The circuit pattern 35 can be electrically connected by vias to the middle layers. The external contact pads 30 have already been described above.

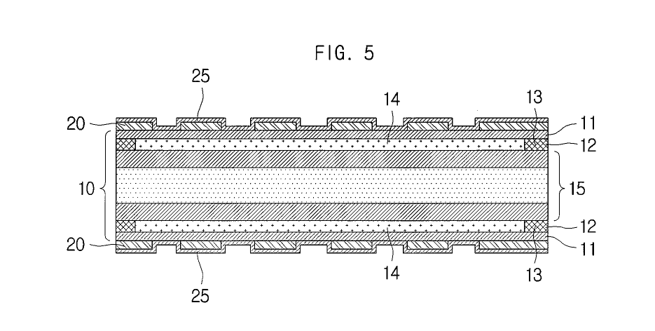

The circuit pattern 35 and the external contact pads 30 can be formed by filling the openings with a metal. In particular, if a plating method is to be utilized, a seed layer 25 can be formed before forming the mask 27 (S150), as illustrated in FIG. 5. The seed layer 25 may be a thin layer of metal formed by electroless plating on a non-conductive material, such as the insulation layer, and can be formed by deposition methods, sputtering methods, etc.

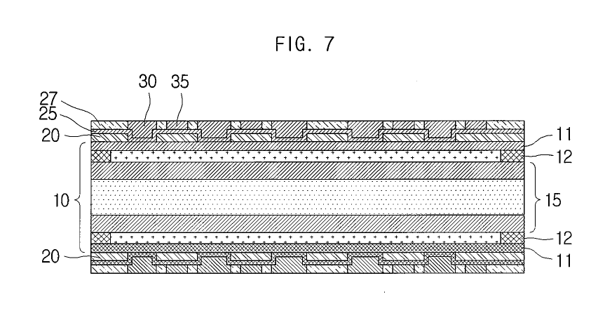

Next, the external contact pads 30 and the circuit pattern 35 may be formed in the openings 21 of the outermost insulation layer 20 and the opening of the mask 27 (S300). If a seed layer 25 has been formed, a plating method can be employed for this operation, using, for example, copper or silver, which exhibit high electrical conductivity. The external contact pads 30 thus formed on one side of the multi-layer PCB can have a thickness substantially equal to the sum of the thickness of the mask 27 and the thickness of the outermost insulation layer 20, so that the external contact pads 30 and the circuit pattern 35 may be made to have different thicknesses, as illustrated in FIG. 7.

Forming an additional outermost insulation layer on one side of the multi-layer PCB in this manner is to prevent warpage.

Warpage may occur frequently in thin multi-layer PCB's. Since the PCB is made from a variety of materials, the differences in various mechanical properties, such as the coefficient of thermal expansion, etc., can cause deformations. As this warpage can cause faulty connections between layers and increase the risk of damage to the multi-layer PCB, it is very important to prevent warpage.

In particular, in the case of a multi-layer PCB formed by a build-up process performed from one side to the other side, the stacking of the build-up layer may entail several repetitions of thermal treatment operations, where the number of thermal treatment repetitions may be different between those layers that are stacked earlier and those that are stacked later. Thus, when the carrier is subsequently removed, this difference can cause warpage, bending the PCB in a “U” shape.

While it is possible to somewhat reduce warpage by applying a thicker layer of solder resist on one side of the multi-layer PCB that is uncovered after the carrier 10 is removed than on the other side, there is a limit to how much the thickness of the solder resist can be increased, because if the pads are too far from the surface, it can be difficult to mount the semiconductor chip, etc.

To resolve this problem, this embodiment may have a greater height of the external contact pads 30 than the height of the circuit pattern 35, so that the external contact pads 30 are not positioned excessively far from the surface. The circuit pattern 35 may be separated from the surface by an amount substantially equal to the thicknesses of the second solder resist layer 55, which will be described later in further detail, and the outermost insulation layer 20, so that the thickness of the insulation layer on one side may be increased to better resist warpage.

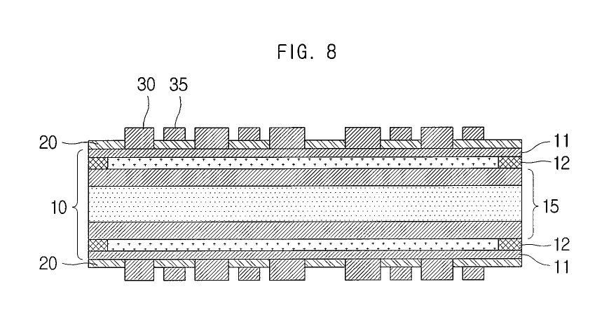

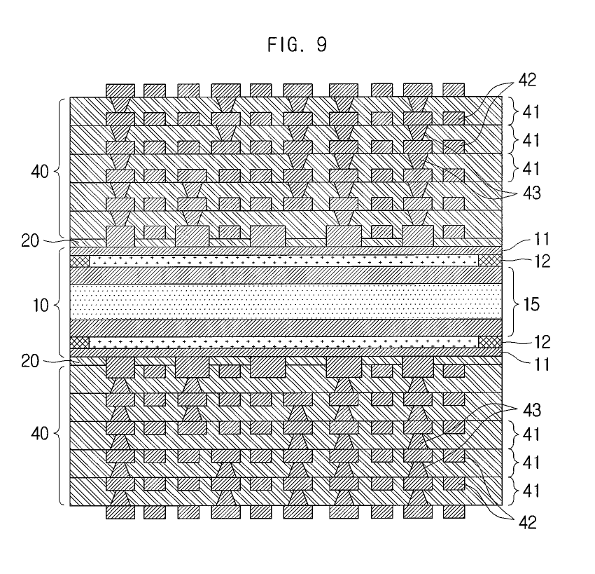

Next, as illustrated in FIG. 8, the mask 27 and the seed layer 25 may be removed (S400 and S450, respectively), to expose the outermost insulation layer 20. Then, as illustrated in FIG. 9, a multiple number of layers 41 that include patterns 42 and vias 43 may be stacked on the outermost insulation layer 20, such that the external contact pads 30 and the circuit pattern 35 are covered, to form a build-up layer 40 (S500).

The build-up layer 40 refers to the stack of layers 41 on which the patterns 42 are formed. Each layer 41 can include one or more vias 43 for electrically interconnecting layers. That is, a required number of layers 41 may be formed by stacking an insulating material on the outermost insulation layer 20, the circuit pattern 35, and the external contact pads 30, forming via holes, and then plating the pattern 42 and the vias 43. Here, the uppermost layer 41 stacked lastly can also include pads for connecting to an external device, but these pads may not be as thick as the external contact pads 30 described above.

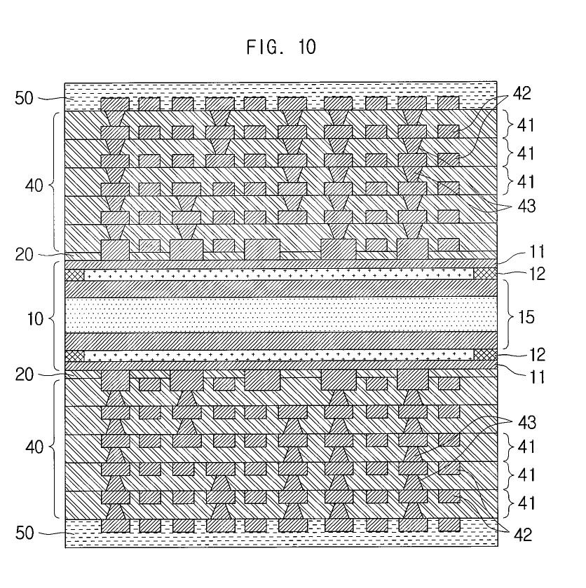

Then, as illustrated in FIG. 10, a first solder resist layer 50 may be formed on the build-up layer 40 (S600), to protect the pattern on the other side of the multi-layer PCB.

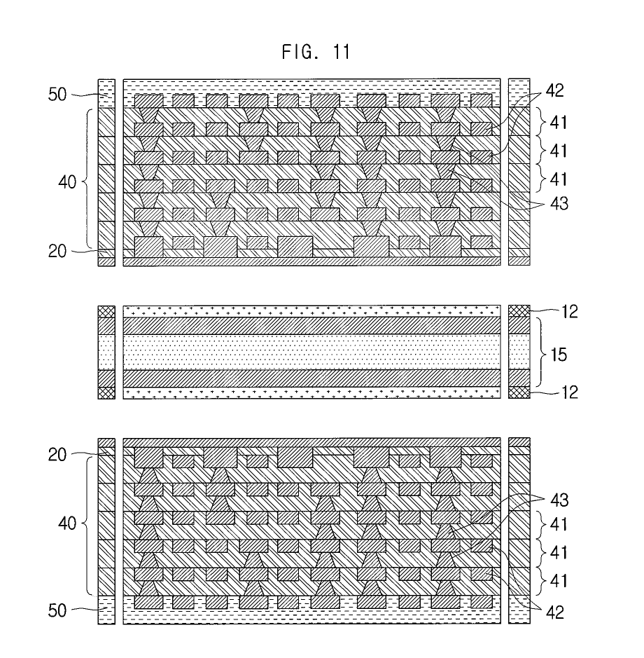

Next, the carrier 10 may be removed (S700). The method of removing the carrier 10 may vary, according to the shape of the carrier 10. Since, in this particular embodiment, the carrier 10, which includes the separation layers 12 and the metal layers 11, is used as described above, the method of removing the carrier 10 can include removing the dummy area by routing (S720), as illustrated in FIG. 11, to cut off the portions of the carrier 10 on which the adhesive 13 is applied.

As the portions of the separation layers 12 where the adhesive 13 is applied are cut off, the CCL 15 part of the carrier 10 may be separated from the multi-layer PCB, leaving only the metal layer 11 on one side of the multi-layer PCB.

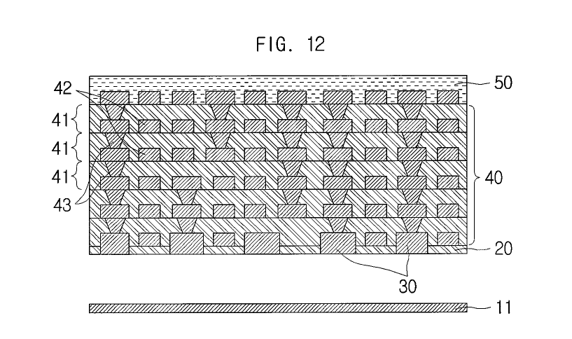

The remaining metal layer 11 may be etched (S740) to expose the outermost insulation layer 20 and the external contact pads (see FIG. 12). Here, if the metal layer 11 includes a metal that reacts with a different etchant from that for the metal of the external contact pads 30 exposed at the surface of the multi-layer PCB, the metal layer 11 can be removed without damaging the external contact pads 30.

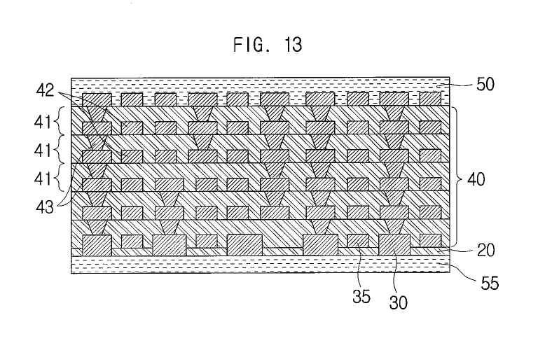

Next, as illustrated in FIG. 13, the second solder resist layer 55 may be formed on the outermost insulation layer 20 (S800). The one side of the multi-layer PCB may be covered by the outermost insulation layer 20, and the circuit pattern 35 may not be exposed. As such, unlike the first solder resist layer 50, the second solder resist layer 55 may serve more to prevent warpage than to protect the circuit.

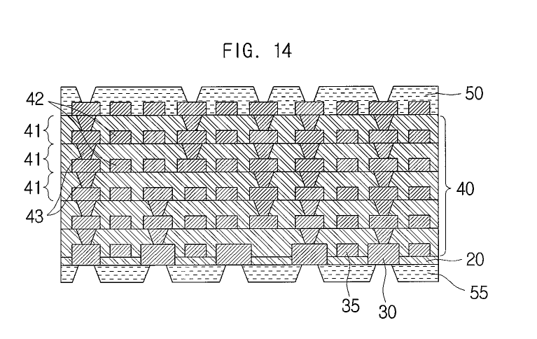

Next, as illustrated in FIG. 14, openings can be formed in the second solder resist layer 55 such that the external contact pads 30 are exposed (S900). The openings can be formed using a laser drill, etc.

As set forth above, certain embodiments of the invention can be utilized to prevent warpage during the manufacture of the PCB, using existing processes for stacking the build-up layer 40 without having to add materials, such as metals, etc., that are resistant to warpage.

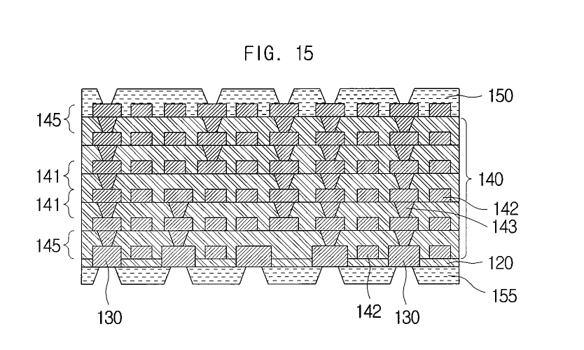

FIG. 15 is a cross-sectional view of a multi-layer PCB according to another aspect of the invention. Illustrated in FIG. 15 are an outermost insulation layer 120, external contact pads 130, a build-up layer 140, layers 141, 145, patterns 142, vias 143, outermost layers 145, a first solder resist layer 150, and a second solder resist layer 155.

This embodiment relates to a multi-layer PCB having solder resist layers 150, 155 formed on both sides of the build-up layer 140, where the build-up layer 140 may be formed by stacking a multiple number of layers 141, in which vias 143 and patterns 142 are formed, from one side to the other. In particular, the layers 145 on the outermost sides may further include external contact pads 130, which may serve as contact terminals when a semiconductor chip, etc., is mounted. In FIG. 15, “one side” refers to the bottom side. As described above, warpage may occur in a build-up layer 140 stacked in one direction after the carrier is separated, with the build-up layer 140 bending in a “U” shape.

To prevent such warpage, an outermost insulation layer 120 may additionally be formed on one side that serves as a reinforcing element. In this case, since the external contact pads 130, which are covered by the outermost insulation layer 120, are to be exposed at the surface, the external contact pads 130 on the one side may penetrate the outermost insulation layer 120 to be uncovered at the one side of the multi-layer PCB. As such, the external contact pads 130 on one side may be thicker than existing pads for connecting to semiconductor components by a thickness substantially equal to the thickness of the outermost insulation layer 120. The risk and prevention of warpage have already been described above in the section describing the method of manufacturing a multi-layer PCB, and thus will not be described again.

As set forth above, certain embodiments of the invention can be utilized to prevent warpage during the manufacture of the PCB, using existing processes for stacking the build-up layer 40 without having to add materials, such as metals, etc., that are resistant to warpage.

While the spirit of the invention has been described in detail with reference to particular embodiments, the embodiments are for illustrative purposes only and do not limit the invention. It is to be appreciated that those skilled in the art can change or modify the embodiments without departing from the scope and spirit of the invention.

Many embodiments other than those set forth above can be found in the appended claims.

What is claimed is:

1. A method of manufacturing a multi-layer printed circuit board having at least one external contact pad formed on one side thereof, the method comprising:
forming an outermost insulation layer having an opening formed therein corresponding with the external contact pad;
forming a mask on the outermost insulation layer, the mask having an opening formed therein corresponding with the external contact pad and with a circuit pattern;
forming the external contact pad and the circuit pattern in the opening of the outermost insulation layer and the opening of the mask;
removing the mask;
forming a build-up layer by stacking at least one layer over the outermost insulation layer such that the external contact pad and the circuit pattern are covered;
forming a first solder resist layer on the build-up layer; and
forming a second solder resist layer on a side of the outermost insulation layer opposite the side having the build-up layer formed thereon; and
forming an opening in the second solder resist layer such that the external contact pad is exposed.

2. The method of claim 1, wherein the outermost insulation layer is formed over a carrier,
and the method further comprises, before the forming of the second solder resist layer, removing the carrier.

3. The method of claim 2, wherein the carrier comprises a metal layer on a surface thereof.

4. The method of claim 3, wherein the metal layer contains a material etchable by a different etchant from that for the external contact pad.

5. The method of claim 3, wherein the opening of the outermost insulation layer is formed by:
stacking the outermost insulation layer on the metal layer of the carrier; and
selectively removing the outermost insulation layer with a laser drill.

6. The method of claim 3, wherein:
the build-up layer includes a dummy area along a perimeter thereof, the dummy area to be removed from a completed multi-layer printed circuit board;
the carrier comprises a separation layer having an adhesive applied only to a portion thereof corresponding with the dummy area; and
the removing of the carrier comprises:
removing the adhesive-applied portion of the separation layer by cutting the dummy area; and
etching the metal layer.

7. The method of claim 1, further comprising:
forming a seed layer, before the forming of the mask;
plating over the seed layer, for the forming of the external contact pad and the circuit pattern; and
removing the seed layer, after the removing of the mask.

8. A multi-layer printed circuit board comprising:
a build-up layer formed by stacking at least one layer from one side to the other side, the layer comprising a via and a pattern formed therein;
a first solder resist layer stacked on the other side of the build-up layer;
an outermost insulation layer stacked on one side of the build-up layer;
an external contact pad formed on one side of the build-up layer, the external contact pad penetrating through the outermost insulation layer and exposed at a surface; and
a second solder resist layer stacked on the outermost insulation layer and having an opening formed therein, the opening exposing the external contact pad.
